(19) United States
(12) Patent Application Publication
(10) Pub. No.: US 2025/0138082 A1
(43) Pub. Date: May 1, 2025

(54) DEPOSITION APPARATUS

(71) Applicant: Samsung Display Co., LTD., Yongin-si (KR)

(72) Inventor: Sung Min HUR, Yongin-si (KR)

(21) Appl. No.: 18/742,451

(22) Filed: Jun. 13, 2024

(30) Foreign Application Priority Data
Oct. 26, 2023 (KR) 10-2023-0144828

(51) Int. Cl. G01R 31/28; C23C 14/52; C23C 16/52

(52) U.S. Cl. CPC G01R 31/2836; C23C 14/52; C23C 16/52

(57) ABSTRACT

A deposition apparatus includes: a reaction chamber; a radio frequency (RF) power supply device configured to provide RF power to the reaction chamber; an RF sensing device configured to sense the RF power at each sub-unit time of each of multiple unit times; a computing device configured to compute an average value of intensities of the RF power measured at each sub-unit time of each of the unit times; and a fault detection and classification (FDC) device configured to: determine an occurrence of an arc based on the calculated average value of the intensities of the RF power; and generate a command signal based on the occurrence of the arc to control a reaction process.

### CROSS-REFERENCE TO RELATED APPLICATION

The present application claims priority to and the benefit of Korean Patent Application No. 10-2023-0144828, filed on Oct. 26, 2023, in the Korean Intellectual Property Office, the entire disclosure of which is incorporated herein by reference.

### BACKGROUND

### 1. Field

Aspects of some embodiments of the present disclosure relate to a deposition apparatus.

### 2. Description of the Related Art

As the information society develops, consumer demand for display devices to show images is increasing in various forms. Display devices may include, for example, liquid crystal display (LCD) devices, field emission display (FED) devices, light-emitting display devices, etc. Light-emitting display devices may include organic light-emitting display devices that include organic light-emitting diode (OLED) elements, and inorganic light-emitting display devices that include inorganic light-emitting diode (LED) elements.

Meanwhile, a display panel, which constitutes a display device, may include various conductive layers and insulating layers formed in a layered structure on a substrate. The various conductive and insulating layers formed on the substrate may be created through a deposition process.

The above information disclosed in this Background section is only for enhancement of understanding of the background and therefore the information discussed in this Background section does not necessarily constitute prior art.

### SUMMARY

Aspects of some embodiments of the present disclosure include a deposition apparatus capable of detecting an arc phenomenon in real time.

Aspects of some embodiments of the present disclosure also include a deposition apparatus with relatively improved accuracy in arc judgement.

However, the characteristics of embodiments according to the present disclosure are not restricted to those set forth herein. The above and other characteristics of embodiments according to the present disclosure will become more apparent to one of ordinary skill in the art to which the present disclosure pertains by referencing the detailed description of the present disclosure given below.

According to some embodiments of the present disclosure, a deposition apparatus includes, a reaction chamber, a radio frequency (RF) power supply device configured to provide RF power to the reaction chamber, an RF sensing device configured to sense the RF power at each sub-unit time of each of multiple unit times, a computing device configured to compute an average value of intensities of the RF power measured at each sub-unit time of each of the unit times, and a fault detection & classification (FDC) device configured to determine the occurrence of an arc based on the calculated average value of the intensities of the RF power.

According to some embodiments, the RF power includes forward wave power and reflected wave power, and an intensity of the RF power is the same as a sum of intensities of the forward wave power and the reflected wave power.

According to some embodiments, the unit times include a first unit time, a second unit time, and a third unit time in chronological order, an average value of intensities of the forward wave power computed during the first unit time is FPn−2, an average value of intensities of the forward wave power computed during the second unit time is FPn−1, an average value of intensities of the forward wave power computed during the third unit time is FPn, the FDC device is further configured to generate a “GO” command if Equation (1) is not satisfied, and Equation (1) is as follows,

$$FPn \leq ( FPn - 2 + FPn - 1 ) / 2 * σ1 , 0.7 \leq σ 1 \leq 0.9 . \qquad ( 1 )$$

According to some embodiments, the FDC device is further configured to generate a “WARNING” command if Equation (1) is satisfied and Equation (2) is not satisfied, and Equation (2) is as follows,

$$FPn \leq ( FPn - 2 + FPn - 1 ) / 2 * σ2 , 0.2 \leq σ 2 \leq 0.5 . \qquad ( 2 )$$

According to some embodiments, the FDC device is further configured to generate a “STOP” command if both Equations (1) and (2) are satisfied.

According to some embodiments, the unit times include a first unit time, a second unit time, and a third unit time in chronological order, an average value of intensities of the reflected wave power computed during the first unit time is RPn−2, an average value of intensities of the reflected wave power computed during the second unit time is RPn−1, an average value of intensities of the reflected wave power computed during the third unit time is RPn, the FDC device is further configured to generate a “GO” command if Equation (3) is not satisfied, and Equation (3) is as follows,

$$RPn \geq ( RPn - 2 + RPn - 1 ) / 2 * σ3 , 1.1 \leq σ3 \leq 1.3 . \qquad ( 3 )$$

According to some embodiments, the FDC device is further configured to generate a “WARNING” command if Equation (3) is satisfied and Equation (4) is not satisfied, and Equation (4) is as follows,

RPn≥(RPn−2+RPn−1)/2*σ4, 1.5≤σ4≤1.8 (4).

According to some embodiments, the FDC device is further configured to generate a “STOP” command if both Equations (3) and (4) are satisfied.

According to some embodiments, 100 or more sub-unit times are included in each of the unit times.

According to some embodiments, the sub-unit times are 10 milliseconds (msec) or less.

According to some embodiments, the sub-unit times are 1 msec.

According to some embodiments, the unit times are 2 second (sec).

According to some embodiments, the unit times are 1 sec.

According to some embodiments, the RF sensing device includes at least one of a data acquisition (DAQ) system or a programmable logic controller (PLC) system.

According to some embodiments of the present disclosure, there is provided a deposition apparatus including, a reaction system including a reaction chamber and a radio frequency (RF) power supply device configured to provide RF power to the reaction chamber, and an inspection system, the inspection system including, an RF sensing device configured to sense the RF power at each sub-unit time of each of multiple unit times and thereby generate a plurality of RF sensing signals including information on an intensity of the RF power, a computing device configured to collect the RF sensing signals at each of the unit times and thereby generate a plurality of processed data signals including information on an average value of intensities of the RF power measured at each sub-unit time of each of the unit times, and a fault detection & classification (FDC) device configured to determine a state of the RF power based on the processed data signals and generate a command signal for the state of the RF power, wherein the FDC device is further configured to provide the command signal to the reaction system.

According to some embodiments, the RF power includes forward wave power and reflected wave power, and an intensity of the RF power is the same as a sum of intensities of the forward wave power and the reflected wave power.

According to some embodiments, the unit times include a first unit time, a second unit time, and a third unit time in chronological order, an average value of intensities of the forward wave power computed during the first unit time is FPn−2, an average value of intensities of the forward wave power computed during the second unit time is FPn−1, an average value of intensities of the forward wave power computed during the third unit time is FPn, the FDC device is further configured to generate a “GO” command if Equation (1) is not satisfied, and Equation (1) is as follows,

$$FPn \leq ( FPn - 2 + FPn - 1 ) / 2 * σ1 , 0.7 \leq σ1 \leq 0.9 . \qquad ( 1 )$$

According to some embodiments, the FDC device is further configured to generate a “WARNING” command if Equation (1) is satisfied and Equation (2) is not satisfied, Equation (2) is as follows,

$$FPn \leq ( FPn - 2 + FPn - 1 ) / 2 * σ2 , 0.2 \leq σ 2 \leq 0.5 , \qquad ( 2 )$$

and the FDC device is further configured to generate a “STOP” command if both Equations (1) and (2) are satisfied.

According to some embodiments, the unit times include a first unit time, a second unit time, and a third unit time in chronological order, an average value of intensities of the reflected wave power computed during the first unit time is RPn−2, an average value of intensities of the reflected wave power computed during the second unit time is RPn−1, an average value of intensities of the reflected wave power computed during the third unit time is RPn, the FDC device is further configured to generate a “GO” command if Equation (3) is not satisfied, and Equation (3) is as follows,

$$RPn \geq ( RPn - 2 + RPn - 1 ) / 2 * σ3 , 1.1 \leq σ3 \leq 1.3 . \qquad ( 3 )$$

According to some embodiments, the FDC device is further configured to generate a “WARNING” command if Equation (3) is satisfied and Equation (4) is not satisfied, Equation (4) is as follows, RPn≥(RPn−2+RPn−1)/2*σ4, 1.5≤σ4≤1.8 . . . (4), and the FDC device is further configured to generate a “STOP” command if both Equations (3) and (4) are satisfied.

According to the aforementioned and other embodiments of the present disclosure, an arc phenomenon can be detected in real time.

Additionally, the accuracy of arc judgement can be relatively improved.

It should be noted that the characteristics of embodiments according to the present disclosure are not limited to those described above, and other characteristics of embodiments according to the present disclosure will be more apparent from the following description.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a block diagram of a deposition apparatus according to some embodiments of the present disclosure;

FIG. 2 is a perspective view of the deposition apparatus according to some embodiments of the present disclosure;

FIG. 3 is a cross-sectional view of a reaction chamber according to some embodiments of the present disclosure;

FIG. 4 is a block diagram illustrating an operating method of an inspection system, according to some embodiments of the present disclosure;

FIG. 5 is a flowchart illustrating the operating method of the inspection system, according to some embodiments of the present disclosure;

FIG. 6 is a graph showing a data computation process of the inspection system according to some embodiments of the present disclosure;

FIG. 7 is a graph showing a judgement process of the inspection system according to some embodiments of the present disclosure;

FIG. 8 is a graph showing changes in high-frequency power sensed by the inspection system according to some embodiments of the present disclosure;

FIG. 9 is a flowchart illustrating an operating method of the inspection system, according to some embodiments of the present disclosure;

FIG. 10 is a plan view of a display device according to some embodiments of the present disclosure;

FIG. 11 is a cross-sectional view of the display device according to some embodiments of the present disclosure; and

FIG. 12 is an enlarged cross-sectional view of the area A of FIG. 11.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, aspects of some embodiments according to the present disclosure will be described in more detail with reference to the accompanying drawings.

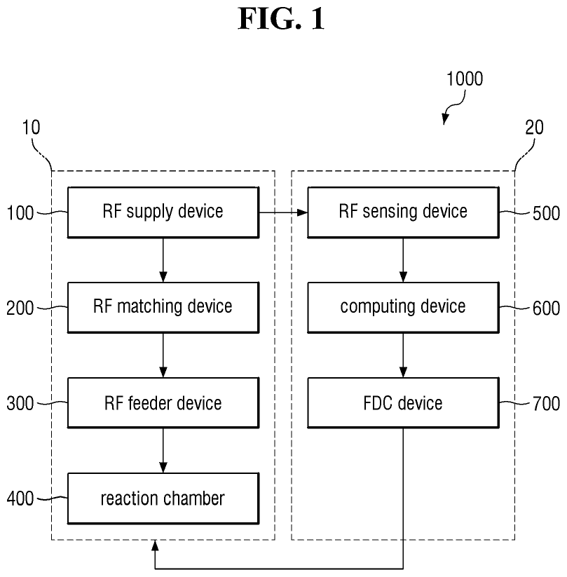

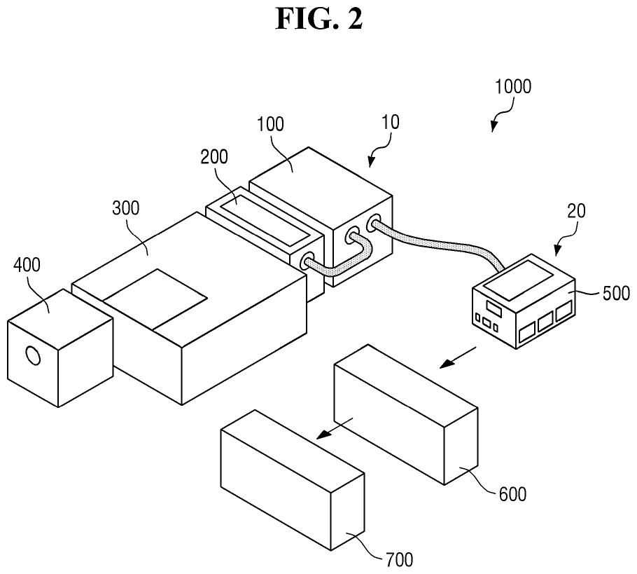

FIG. 1 is a block diagram of a deposition apparatus according to some embodiments of the present disclosure. FIG. 2 is a perspective view of the deposition apparatus according to some embodiments of the present disclosure.

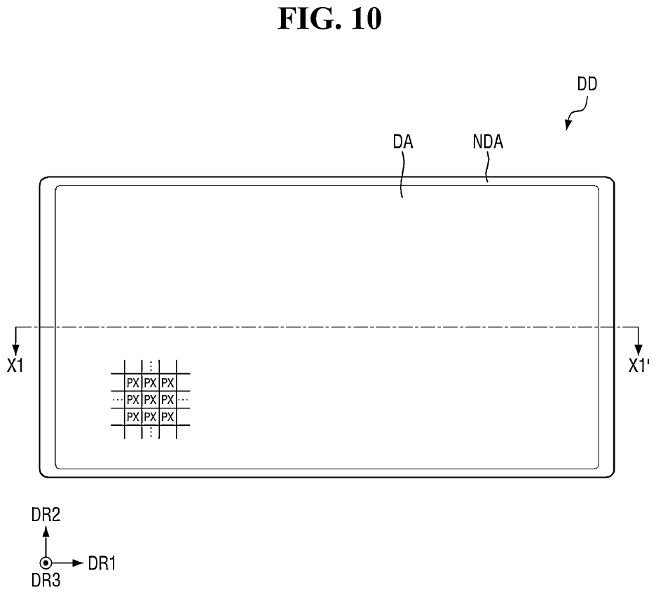

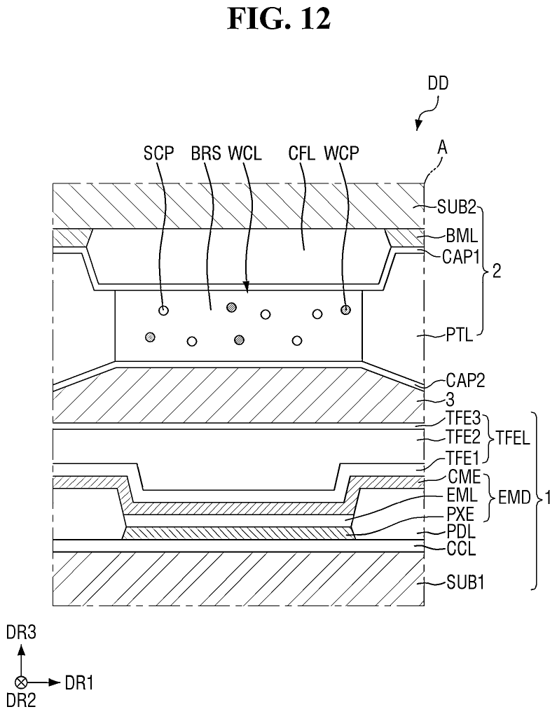

Referring to FIGS. 1 and 2, a deposition apparatus 1000, which is a type of vapor deposition apparatus, may be an apparatus for depositing a plurality of thin films on a display device (“DD” of FIG. 10). For example, the deposition apparatus 1000 may be a manufacturing device for a display device to form one or more thin-film layers (e.g., a metal film, an oxide film, a nitride film, a carbide film, and/or a sulfide film) or a stacked structure of such thin film layers. According to some embodiments, the deposition apparatus 1000 may be a manufacturing device intended to form a stack of inorganic and organic films included in a thin-film encapsulation layer (“TFEL” of FIG. 12) of the display device DD.

According to some embodiments, the deposition apparatus 1000 may be any one of a chemical vapor deposition (CVD) apparatus, a plasma enhanced CVD (PECVD) apparatus, a physical vapor deposition (PVD) apparatus, and an atomic layer deposition (ALD) apparatus.

The deposition apparatus 1000 may include a reaction system 10 and an inspection system 20.

The reaction system 10 may be a system that performs a reaction process for the deposition apparatus 1000. For example, the reaction system 10 may perform a deposition process for the deposition apparatus 1000. The reaction system 10 may include a radio frequency (RF) power supply device 100, an RF matching device 200, an RF feeder device 300, and a reaction chamber 400.

The RF power supply device 100 may apply RF power to the inside of the reaction chamber 400. The RF power applied by the RF power supply device 100 may create an electric field within the reaction chamber 400. The electric field may convert several reaction gases or source gases into a plasma state.

The RF matching device 200 may match the impedance between the RF power supply device 100 and the reaction chamber 400. For example, the RF matching device 200 may adjust the impedance by controlling the ratio of forward wave power and reflected wave power among the RF power generated by the RF power supply device 100. Consequently, the RF matching device 200 can minimize or reduce the energy loss of the RF power generated by the RF power supply device 100 and can effectively deliver the RF power to the reaction chamber 400.

Meanwhile, RF power may include forward wave power and reflected wave power. The forward wave power may be the power used to reach the reaction chamber 400 and form plasma, while the reflected wave power may be the power reflected back from the reaction chamber 400.

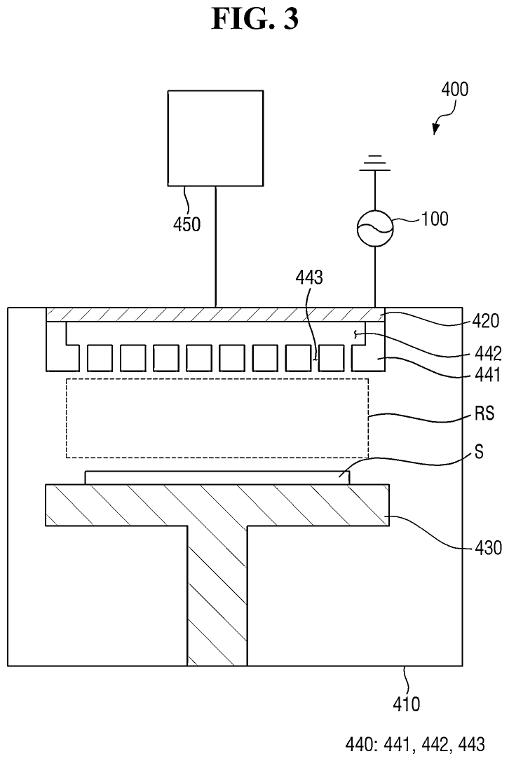

The RF feeder device 300 may supply impedance-matched RF power from the RF frequency matching device 200 into the reaction chamber 400. The RF feeder device 300 may apply RF power to an upper electrode (“420” of FIG. 3) within the reaction chamber 400. The RF feeder device 300 may also control and maintain plasma by adjusting the state of the electric field generated within the reaction chamber 400.

The reaction chamber 400 may partition the internal space necessary for the reaction process of the reaction system 10. The reaction chamber 400 may maintain atmospheric pressure or a vacuum state depending on the stage of processing. Details of the configuration of the reaction chamber 400 will be presented later with reference to FIG. 3.

The inspection system 20 may detect an arc phenomenon in real time during the reaction process of the reaction system 10. For example, the inspection system 20 may detect the occurrence of an arc by analyzing the RF power of the reaction system 10. An arc phenomenon is an abnormal electrical discharge phenomenon that may cause instability in plasma due to an unstable RF power state. The occurrence of an arc may lead to equipment damage, deterioration in thin film quality, and other safety issues. The inspection system 20 may address such problems by detecting the occurrence of an arc in real time.

The inspection system 20 may include a RF sensing device 500, a computing device 600, and a fault detection & classification (FDC) device 700.

The RF sensing device 500 may sense and measure the state of the RF power generated from the RF power supply device 100. For example, the RF sensing device 500 may sense and measure at least one of forward wave power or reflected wave power included in the generated RF power.

According to some embodiments, the RF sensing device 500 may include at least one of a data acquisition (DAQ) system or a programmable logic controller (PLC) system.

The computing device 600 may process information on multiple RF powers sensed by the RF sensing device 500. For example, the computing device 600 may compute the average value of the intensities of the multiple RF powers sensed by the RF sensing device 500 over a period of time (e.g., a set or predetermined period of time).

The fault detection & classification (FDC) device 700 may use processed data from the computing device 600 to determine the presence of anomalies based on judgement logic. For example, the FDC device 700 may determine the occurrence of an arc based on the intensity of RF power included in the processed data from the computing device 600.

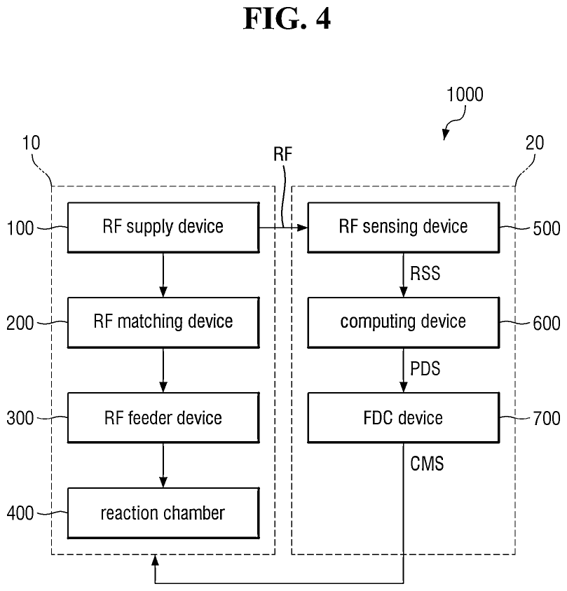

Further detailed description of the inspection system 20 will be provided later with reference to FIG. 4 and other figures.

FIG. 3 is a cross-sectional view of a reaction chamber according to some embodiments of the present disclosure.

Referring to FIG. 3, the reaction chamber 400 may include a chamber 410, an upper electrode 420, a susceptor 430, a shower head 440, and a gas supply unit 450.

The chamber 410 may partition the internal space necessary for processing. Various components that will be described later may be located in the internal space of the chamber 410. The chamber 410 may maintain atmospheric pressure or a vacuum state depending on the stage of processing. Additionally, the internal space of the chamber 410 may be connected to the external environment or may be sealed depending on the stage of processing.

The upper electrode 420 may be located at an upper part of the internal space of the chamber 410. The upper electrode 420 may receive RF power from the RF power supply device 100. When the RF power supply device 100 applies RF power to the upper electrode 420, an electric field may be generated between the upper electrode 420 and the susceptor 430. The generated electric field may convert several gases into a plasma state.

The susceptor 430 may be located at a lower part of the internal space of the chamber 410. The susceptor 430 may face the upper electrode 420. The susceptor 430 may be arranged at a distance from the upper electrode 420. The susceptor 430 may function as a lower electrode.

The susceptor 430 may support a substrate S, which is a target subjected to processing. According to some embodiments, the substrate S may be an insulating substrate used in the display device DD of FIG. 10.

According to some embodiments, the susceptor 430 may be connected to driving means that elevates the substrate S. Thus, the substrate S, mounted on the susceptor 430, may be moved upward or downward in the internal space of the chamber 410, as needed.

A reaction space RS may be defined between the upper electrode 420 and the susceptor 430. The reaction space RS may be defined as a space where several gases, such as a reaction gas and a source gas, react.

The shower head 440 may be located between the upper electrode 420 and the susceptor 430. The shower head 440 may include a body 441, a gas inlet space 442, and shower holes 443.

The body 441 may partition the gas inlet space 442. According to some embodiments, the gas inlet space 442 may be partitioned by the body 441 and the upper electrode 420.

According to some embodiments, the body 441 of the shower head 440 may be formed of aluminum or an aluminum alloy, but the present disclosure is not limited thereto. Alternatively, according to some embodiments, the body 441 of the shower head 440 may be made of stainless steel (SUS).

The shower head 440 may include a plurality of shower holes 443, which are open toward the reaction space RS. According to some embodiments, the shower holes 443 may connect the gas inlet space 442 and the reaction space RS. Gases filled in the gas inlet space 442 may be provided to the reaction space RS through the shower holes 443.

The gas supply unit 450 may supply reaction gases, source gases, and cleaning gases for use in a deposition process. The gas supply unit 450 may supply these gases into the chamber 410. For example, the gas supply unit 450 may supply these gases to the gas inlet space 442, and the gases supplied to the gas inlet space 442 may be provided to the reaction space RS through the shower holes 443.

A single gas supply unit 450 may be provided, but the present disclosure is not limited thereto. Alternatively, a plurality of gas supply units 450 may be provided depending on the types of gases.

During the reaction process, if an arc phenomenon occurs within the reaction chamber 400 of the reaction system 10, problems such as equipment damage and deterioration of thin film quality may occur. An operating method of the inspection system 20 capable of detecting an arc phenomenon in real time will hereinafter be described.

FIG. 4 is a block diagram illustrating an operating method of an inspection system, according to some embodiments of the present disclosure.

Referring to FIG. 4, the inspection system 20 may determine the occurrence of an arc by sensing RF power RF generated by the RF power supply device 100.

For example, the RF power supply device 100 may generate RF and produce the RF power RF.

Thereafter, the RF sensing device 500 may generate an RF sensing signal RSS by sensing the RF power RF (or the intensity of the RF power RF) at regular intervals. The RF sensing signal RSS may include information on the RF power RF (or information on the intensity of the RF power RF). The RF sensing device 500 may provide the RF sensing signal RSS to the computing device 600.

Thereafter, the computing device 600 may generate a processed data signal PDS using the RF power information included in the RF sensing signal RSS. The processed data signal PDS may include processed data. The processed data may include information on the average value of the intensities of multiple RF powers RF sensed over a period of time (e.g., a set or predetermined period of time). The computing device 600 may provide the processed data signal PDS to the FDC device 700.

Thereafter, the FDC device 700 may use the processed data contained in the PDS to determine the occurrence of an arc based on judgement logic. The FDC device 700 may generate a command signal CMS based on the occurrence of an arc. The command signal CMS may include command information for commands such as “GO”, “WARNING”, and “STOP”. The FDC device 700 may provide the command signal CMS to the reaction system 10.

The reaction system 10 may continue the reaction process, alert a user with a warning, or stop the reaction process based on whether the command information included in the command signal CMS is a “GO”, “WARNING”, or “STOP” command.

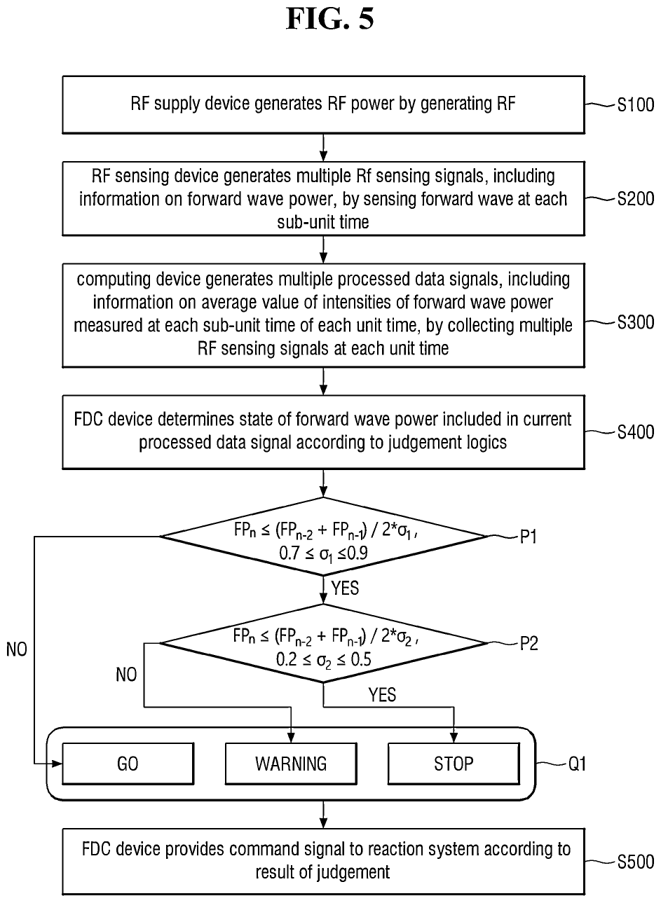

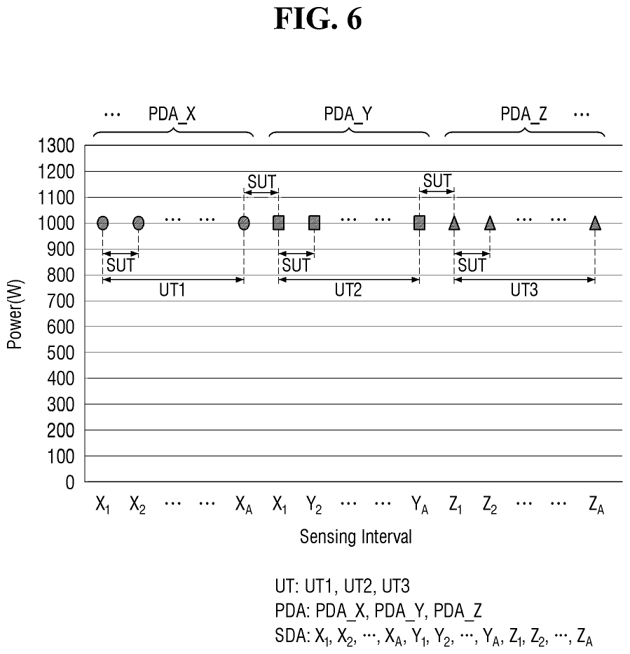

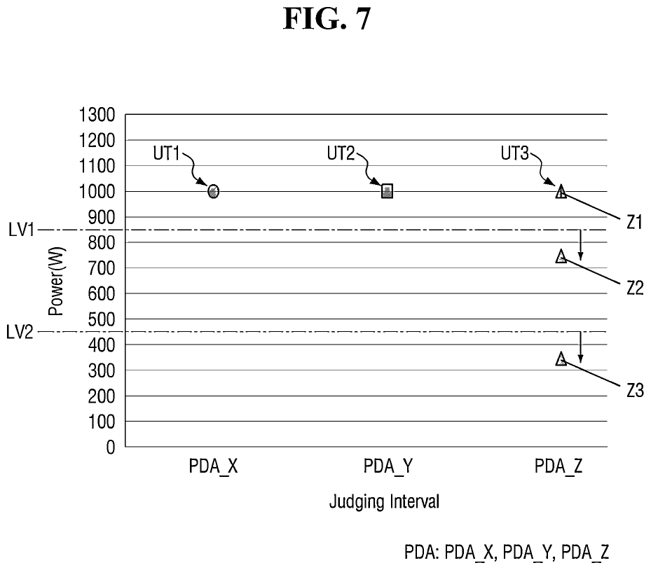

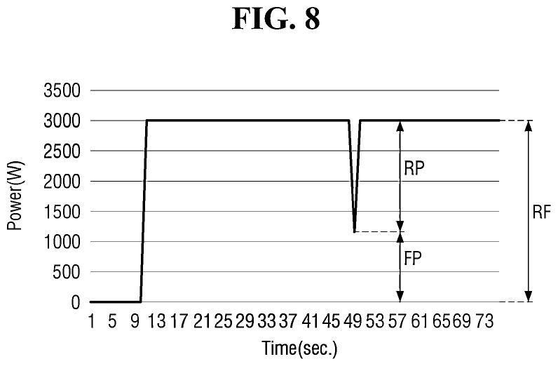

FIG. 5 is a flowchart illustrating the operating method of the inspection system according to some embodiments of the present disclosure. FIG. 6 is a graph showing a data computation process of the inspection system according to some embodiments of the present disclosure. FIG. 7 is a graph showing a judgement process of the inspection system according to some embodiments of the present disclosure. FIG. 8 is a graph showing changes in high-frequency power sensed by the inspection system according to some embodiments of the present disclosure.

Referring to FIGS. 5 through 8 and further to FIG. 4, first, the RF power supply device 100 may generate RF to produce RF power RF (S100).

The RF power RF may include forward wave power FP and reflected wave power RP. The forward wave power FP may be power used to reach the reaction chamber 400 and form plasma, while the reflected wave power RP may be power reflected back from the reaction chamber 400.

The RF power RF excluding the forward wave power FP may be the reflected wave power RP. The total intensity of the RF power RF may be the sum of the intensities of the forward wave power FP and reflected wave power RP. For example, as illustrated in FIG. 8, when the total intensity of the RF power RF is 3000 W and the reflected wave power RP is 0 W, the forward wave power FP may be 3000 W. If the total intensity of the RF power RF is 3000 W and the reflected wave power RP is 1800 W, the forward wave power FP may be 1200 W.

Second, the RF sensing device 500 may sense RF at each sub-unit time SUT and may generate a plurality of radio frequency sensing signals RSS including information on the RF power RF (S200).

For example, the RF sensing device 500 may sense the forward wave power FP or the reflected wave power RP by sensing a forward wave or a reflected wave at each sub-unit time SUT. According to some embodiments, each sub-unit time SUT may be approximately 10 milliseconds (msec) or less. According to some embodiments, each sub-unit time SUT may be 1 msec.

Because the intensity of the RF power RF is the sum of the intensities of the forward wave power FP and reflected wave power RP, the intensity of one of the forward wave power FP and reflected wave power RP can be identified by measuring the intensity of the other power. For convenience of explanation, the RF sensing device 500 will hereinafter be described as sensing the forward wave power FP.

Thereafter, the RF sensing device 500 may generate a plurality of RF sensing signals RSS, including forward wave power information (or forward wave power intensity information), by sensing the forward wave power FP. The RF sensing device 500 may provide the RF sensing signals RSS to the computing device 600.

Third, the computing device 600 may generate a plurality of processed data signals PDS, including information on the average value of the intensities of the forward wave power FP measured at each sub-unit time SUT of each unit time UT, by collecting the RF sensing signals RSS during the unit time UT (S300).

For example, the computing device 600 may collect a plurality of RF sensing signals RSS at each unit time UT. A unit time UT may be longer than a sub-unit time SUT. According to some embodiments, a unit time UT may be up to 2 seconds (sec). According to some embodiments, a unit time UT may be 1 sec.

According to some embodiments, 100 sub-unit times SUT may be included in each unit time UT. For example, if each unit time UT are 1 sec and each sub-unit time SUT is 1 msec, then 1000 sub-unit times SUT may be included in each unit time UT. In another example, if each unit time UT is 1 sec and each sub-unit time SUT is 10 msec, then 100 sub-unit times SUT may be included in each unit time UT.

In the inspection system 20 of the deposition apparatus 1000, the sensing intervals of the RF sensing device 500, i.e., sub-unit times SUT, may be included in each unit time UT, thereby increasing time resolution (or time discrimination). As a result, the ratio of true arc detections to arc judgments may increase, relatively improving the accuracy of arc judgment.

For example, if the result of the sensing of the RF power RF is classified as an arc judgment and an interlock is initiated to stop the reaction process, and if an arc phenomenon has actually occurred in the reaction chamber 400, the arc judgement may be classified as a true arc detection. If the result of the sensing of the RF power RF is classified as an arc judgment, but no arc phenomenon has occurred in the reaction chamber 400, the arc judgment may be classified as a false arc detection. If the result of the sensing of the RF power RF is classified as an arc judgment and an interlock is initiated, but the arc judgement turns out to be a false arc detection, the reaction process may have been unnecessarily stopped, reducing process efficiency. The inspection system 20 of the deposition apparatus 1000 can have a high time resolution and can thus relatively improve arc judgment accuracy by increasing the ratio of true arc detections to arc judgments.

Thereafter, the computing device 600 may calculate the average value of the intensities of the forward wave power FP measured at each sub-unit time SUT of each unit time UT. The computing device 600 may generate a plurality of processed data signals PDS, including information on the calculated average value. The computing device 600 may provide the processed data signals PDS to the FDC device 700.

Steps S200 and S300 will hereinafter be described with reference to FIG. 6.

Referring to FIG. 6, the radio frequency sensing device 500 may sense the forward wave power FP at each sub-unit time SUT and may thereby generate a plurality of sensing data SDA sensed and collected at each sub-unit time SUT.

For example, the sensing data SDA may include multiple first sensing data (X₁, X₂, . . . X_{A}) measured during a first unit time UT1, multiple second sensing data (Y₁, Y₂, . . . Y_{A}) measured during a second unit time UT2, and multiple third sensing data (Z₁, Z₂, . . . Z_{A}) measured during a third unit time UT3.

The computing device 600 may convert the sensing data SDA measured at each sub-unit time SUT of each unit time UT into a plurality of processed data PDA.

For example, the processed data PDA may include first, second, and third processed data PDA_X, PDA_Y, and PDA_Z. The first processed data PDA_X may be generated by converting the multiple first sensing data (X₁, X₂, . . . , X_{A}) measured during the first unit time UT1. The second processed data PDA_Y may be generated by converting the multiple second sensing data (Y₁, Y₂, . . . , Y_{A}) measured during the second unit time UT2. The third processed data PDA_Z may be generated by converting the multiple third sensing data (Z₁, Z₂, . . . Z_{A}) measured during the third unit time UT3.

The processed data PDA may be the average values of the intensities of forward wave powers FP included in multiple sensing data SDA. For example, the first processed data PDA_X may be the average value of the intensities of forward wave powers FP included in in the multiple first sensing data (X₁, X₂, . . . , X_{A}) measured during the first unit time UT1, the second processed data PDA_Y may be the average value of the intensities of forward wave powers FP included in the multiple second sensing data (Y₁, Y₂, . . . , Y_{A}) measured during the second unit time UT2, and the third processed data PDA_Z may be the average value of the intensities of forward wave powers FP included in the multiple third sensing data (Z₁, Z₂, . . . Z_{A}) measured during the third unit time UT3.

Fourth, the FDC device 700 may determine the state of forward wave power FP included in a current processed data signal PDS for a current unit time UT according to first and second judgement logics P1 and P2 (S400).

For example, the FDC device 700 may determine the state of the forward wave power FP included in the current processed data signal PDS by comparing processed data PDA included in the current processed data signal PDS with processed data PDA included in previous processed data signals PDS for previous unit times UT.

Referring to FIG. 7, if the third processed data PDA_Z of the third unit time UT3 is the processed data PDA of the current unit time UT, the state of the forward wave power FP included in the third processed data PDA_Z may be determined based on the first processed data PDA_X and the second processed data PDA_Y from the two immediately preceding unit times UT, i.e., the first and second unit times UT1 and UT2, but the present disclosure is not limited thereto. Alternatively, the three or more immediately preceding unit times UT may be used.

First and second levels LV1 and LV2 may be set based on the intensities of the forward wave power FP included in the first and second processed data PDA_X and PDA_Y. If the intensities of the forward wave power FP included in the third processed data PDA_Z are below the first level LV1, as indicated by “Z1”, command information Q1 for a “GO” command may be generated. If the intensities of the forward wave power FP included in the third processed data PDA_Z are above the first level LV1 but below the second level LV2, as indicated by “Z2”, command information Q1 for a “WARNING” command may be generated. If the intensities of the forward wave power FP included in the third processed data PDA_Z are above the second level LV2, as indicated by “Z3”, command information Q1 for a “STOP” command may be generated.

The setting of the first and second levels LV1 and LV2 may be performed as follows.

When FPn represents the intensity of forward wave power FP included in the third processed data PDA_Z, FPn−1 represents the intensity of forward wave power FP included in the first processed data PDA_X, and FPn−2 represents the intensity of forward wave power FP included in the second processed data PDA_Y, the current state of the forward wave power FP may be determined according to the first and second judgement logics P1 and P2. The first and second judgement logics P1 and P2 may be represented by Equations (1) and (2), respectively:

$$F {P}_{n} \leq ( F {P}_{n - 2} + F {P}_{n - 1} ) / 2 * {σ}_{1} , 0.7 \leq {σ}_{1} \leq 0.9 ; \qquad ( 1 )$$

$$and$$

$${FP}_{n} \leq ( F {P}_{n - 2} + F {P}_{n - 1} ) / 2 * σ2 , 0.2 \leq {σ}_{2} \leq 0.5 . \qquad ( 2 )$$

If FPₙ does not satisfy Equation (1), the FDC device 700 may generate command information Q1 for a “GO” command. If FPₙ satisfies Equation (2), the FDC device 700 may generate command information Q1 for a “WARNING” command. If FPₙ satisfies neither Equation (1) nor Equation (2), the FDC device 700 may generate command information Q1 for a “STOP” command.

Fifth, the FDC device 700 may provide a command signal CMS to the reaction system 10 based on the result of the judgement performed in S400 (S500).

The command signal CMS may include command information Q1. For example, the command signal CMS may include any one of the command information Q1 for a “GO” command, the command information Q1 for a “WARNING” command, and the command information Q1 for a “STOP” command.

In response to receiving the command signal CMS including the command information Q1 for a “GO” command from the FDC device 700, the reaction system 10 may continue the reaction process. In response to receiving the command signal CMS including the command information Q1 for a “WARNING” command from the FDC device 700, the reaction system 10 may alert the user. The user who receives a warning signal may choose to stop or continue the reaction process. In response to receiving the command signal CMS including the command information Q1 for a “stop” command from the FDC device 700, the reaction system 10 may terminate the reaction process.

FIG. 8 illustrates a graph where the intensity of RF power RF is 3000 W. Referring to FIG. 8, the intensity of forward wave power FP is maintained at 3000 W in a period between about 10 sec and about 50 sec and then decreases to 1200 W around at 50 sec.

Referring to Equation (2) above, if FPₙ represents the intensity of RF power RF around at 50 sec and is 1200 W, and if both FPₙ₋₂ and FPₙ₋₁ are 3000 W with σ2 set to 0.5, then 1200≤(3000+3000)/2*0.5. Because FPₙ satisfies Equation (2), a “STOP” command may be issued.

As the deposition apparatus 1000 includes the inspection system 20, the deposition apparatus 1000 can detect an arc phenomenon in real time during the reaction process. Thus, the deposition apparatus 1000 can prevent or reduce equipment damage, deterioration in thin film quality, and other safety issues caused by an arc phenomenon.

Additionally, the deposition apparatus 1000 can increase the ratio of true arc detections to arc judgements by raising the time resolution of the inspection system 20, and can thereby enhance the accuracy of arc judgement. Consequently, the process efficiency of the deposition apparatus 1000 can be relatively improved.

A deposition apparatus according to some embodiments of the present disclosure will hereinafter be described. In the following embodiments, components identical to those described in the previous embodiments are referred to by the same reference numbers, any redundant explanations will be omitted or simplified, and the differences with the previous embodiments will hereinafter be mainly described.

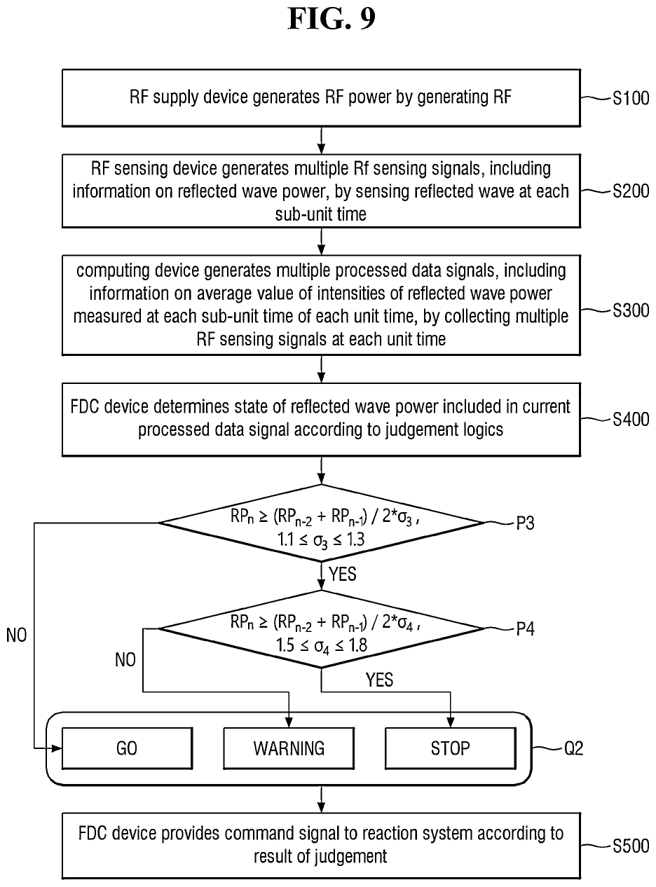

FIG. 9 is a flowchart illustrating an operating method of the inspection system according to some embodiments of the present disclosure.

Referring to FIG. 9, the deposition apparatus 1000 differs from its counterpart of FIG. 5 in that RF power RF sensed by the RF sensing device 500 is reflected wave power RP.

For example, first, the RF power supply device 100 may generate RF to produce RF power RF (S100).

Second, the RF sensing device 500 may generate a plurality of RF sensing signals RSS, including information on the RF power RF, by sensing the RF at each sub-unit time SUT (S200).

Because the intensity of the RF power RF is the sum of the intensities of forward wave power FP and reflected wave power RP, the intensity of one of the forward wave power FP and the reflected wave power RP can be identified by measuring the intensity of the other power. For convenience of explanation, the RF sensing device 500 will hereinafter be described as sensing reflected wave power FP.

The RF sensing device 500 may generate a plurality of RF sensing signals RSS, including information on the reflected wave power RP (or information on the intensity of the reflected wave power RP), by sensing the reflected wave power RP. The RF sensing device 500 may provide the RF sensing signals RSS to the computing device 600.

Third, the computing device 600 may generate a plurality of processed data signals PDS, including information on the average value of the intensities of multiple reflected wave powers RP measured at each sub-unit time SUT, by collecting a plurality of RF sensing signals RSS at each unit time UT (S300).

The computing device 600 may calculate the average value of the intensities of multiple reflected wave powers RP measured at each sub-unit time SUT of each unit time UT. The computing device 600 may generate a plurality of processed data signals PDS, including information on the calculated average value. The computing device 600 may provide the generated processed data signals PDS to the FDC device 700.

Fourth, the FDC device 700 may determine the state of reflected wave power RP contained in a current processed data signal PDS for a current unit UT according to third and fourth judgement logics P3 and P4 (S400).

For example, the FDC device 700 may determine the state of the reflected wave power RP contained in the current processed data signal PDS by comparing processed data PDA included in the current processed data signal PDS with processed data PDA included in previous processed data signals PDS for previous unit times UT.

For example, referring again to FIG. 7, if the third processed data PDA_Z of the third unit time UT3 is the processed data PDA of the current unit time UT, the state of reflected wave power RP included in the third processed data PDA_Z may be determined based on the first processed data PDA_X and the second processed data PDA_Y from the two immediately preceding unit times UT, i.e., the first and second unit times UT1 and UT2, but the present disclosure is not limited thereto. Alternatively, the three or more immediately preceding unit times UT may be used.

When RPₙ represents the intensity of reflected wave power RP included in the third processed data PDA_Z, RPₙ₋₁ represents the intensity of reflected wave power RP included in the first processed data PDA_X, and RPₙ₋₂ represents the intensity of reflected wave power RP included in the second processed data PDA_Y, the current state of the reflected wave power RP may be determined according to the third and fourth judgement logics P3 and P4, and the first and second judgement logics P3 and P4 may be represented by Equations (3) and (4), respectively:

$${RP}_{n} \geq ( {RP}_{n - 2} + {RP}_{n - 1} ) / 2 * {σ}_{3} , 1.1 \leq {σ}_{3} \leq 1.3 ; \qquad ( 3 )$$

$$and$$

$${RP}_{n} \geq ( {RP}_{n - 2} + {RP}_{n - 1} ) / 2 * {σ}_{4} , 1.5 \leq {σ}_{4} \leq 1.8 . \qquad ( 4 )$$

If RPₙ does not satisfy Equation (3), the FDC device 700 may generate command information Q2 for a “GO” command. If RPₙ satisfies Equation (4), the FDC device 700 may generate command information Q2 for a “WARNING” command. If RPₙ satisfies neither Equation (3) nor Equation (4), the FDC device 700 may generate command information Q2 for a “STOP” command.

Fifth, the FDC device 700 may provide a command signal CMS to the reaction system 10 based on the result of the judgement performed in S400 (S500).

The command signal CMS may include command information Q2. For example, the command signal CMS may include any one of the command information Q2 for a “GO” command, the command information Q2 for a “WARNING” command, and the command information Q2 for a “STOP” command.

In response to receiving the command signal CMS including the command information Q2 for a “GO” command from the FDC device 700, the reaction system 10 may continue the reaction process. In response to receiving the command signal CMS including the command information Q2 for a “WARNING” command from the FDC device 700, the reaction system 10 may alert the user. The user who receives a warning signal may choose to stop or continue the reaction process. In response to receiving the command signal CMS including the command information Q2 for a “stop” command from the FDC device 700, the reaction system 10 may terminate the reaction process.

As the deposition apparatus 1000 includes the inspection system 20, the deposition apparatus 1000 can detect an arc phenomenon in real time during the reaction process. Thus, the deposition apparatus 1000 can prevent or reduce equipment damage, deterioration in thin film quality, and other safety issues caused by an arc phenomenon.

Additionally, the deposition apparatus 1000 can increase the ratio of true arc detections to arc judgements by raising the time resolution of the inspection system 20, and can thereby enhance the accuracy of arc judgement. Consequently, the process efficiency of the deposition apparatus 1000 can be relatively improved.

An display device obtained using the deposition apparatus according to any one of the aforementioned embodiments will hereinafter be described.

FIG. 10 is a plan view of a display device according to some embodiments of the present disclosure.

Referring to FIG. 10, a display device DD may refer to any electronic device that provides a display screen. The display device DD may display videos or still images. Examples of the display device DD may include televisions (TVs), laptops, monitors, billboards, Internet of Things (IOT) devices, mobile phones, smartphones, tablet personal computers (PCs), electronic watches, smartwatches, watch phones, head-mounted displays (HMDs), mobile communication terminals, electronic notepads, e-book readers, portable multimedia players (PMPs), navigation systems, gaming consoles, digital cameras, and camcorders.

According to some embodiments, the display device DD may have a rectangular shape in a plan view. The display device DD may have two long sides extended in a first direction DR1 and two short sides extended in a second direction DR2 intersecting the first direction DR1. The corners where the long sides and the short sides of the display device DD meet may be right-angled, but the present disclosure is not limited thereto. Alternatively, the corners of the display device DD may be curved. According to some embodiments, the long sides may extend in the second direction DR2, and the short sides may extend in the first direction DR1. The planar shape of the display device DD is not particularly limited and may be in a circular or another shape.

The first and second directions DR1 and DR2, which are horizontal directions, intersect each other. For example, the first and second directions DR1 and DR2 may be orthogonal to each other. Additionally, a third direction DR3 intersects the first and second directions DR1 and DR2. For example, the third direction DR3 may be a vertical direction orthogonal to the first and second directions DR1 and DR2. Unless otherwise defined, the directions indicated by the arrows for the first, second, and third directions DR1, DR2, and DR3 may be each referred to as one side, and the opposite directions may be each referred to as the opposite side.

The display device DD may include a display panel that provides a display screen. Examples of the display panel include an inorganic light-emitting diode display panel, an organic light-emitting display panel, a quantum dot light-emitting display panel, a plasma display panel (PDP), and a field emission display (FED) panel. The display panel will hereinafter be described as being an organic light-emitting diode display panel, but the present disclosure is not limited thereto. That is, various other display panels may also be used without departing from the scope of the present disclosure.

The display device DD may include a display area DA and a non-display area NDA, which is arranged around the display area DA. The display area DA is an area where the screen is displayed, and the non-display area NDA is an area where the screen is not displayed. The display area DA may also be referred to as an active area, while the non-display area NDA may also be referred to as an inactive area. The display area DA typically occupies the center of the display device DD, and the non-display area NDA may be arranged around the display area DA.

The display area DA may include a plurality of pixels PX. The pixels PX may be arranged in row and column directions. The pixels PX may have a rectangular or square shape in a plan view, but the present disclosure is not limited thereto. Alternatively, the pixels PX may have a rhombus shape with its sides inclined relative to one direction.

As described above, the non-display area NDA may be arranged around the display area DA. The non-display area NDA may partially or completely surround the display area DA. If the display area DA has a rectangular shape, the non-display area NDA may be located adjacent to the four sides of the display area DA. The non-display area NDA may form the bezel of the display device DD. In the non-display area NDA, wirings or circuit driving parts included in the display device DD may be located, or external devices may be mounted.

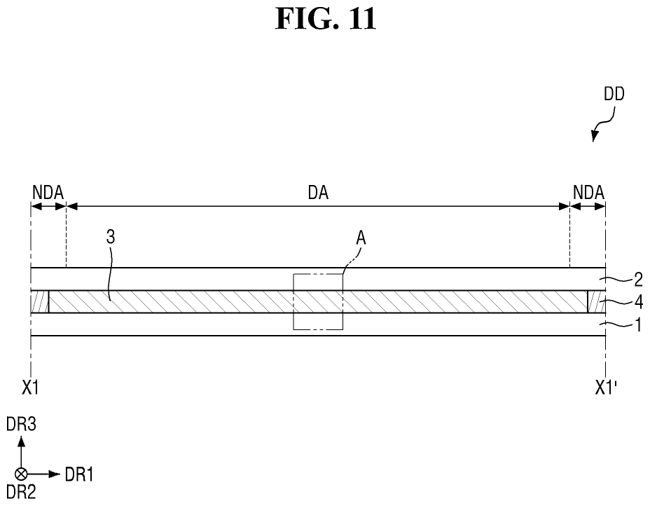

FIG. 11 is a cross-sectional view of the display device according to some embodiments of the present disclosure.

Referring to FIG. 11, the display device DD may include a display substrate 1, a color conversion substrate 2, which faces the display substrate 1, a sealing part 4, which couples the display substrate 1 and the color conversion substrate 2, and a filler 3, which is filled between the display substrate 1 and the color conversion substrate 2.

The display substrate 1 may include components and circuits for displaying an image, such as pixel circuits (e.g., switching elements), a pixel-defining film, which defines light-emitting areas and non-light-emitting areas, and self-light-emitting elements. According to some embodiments, the self-light-emitting elements may include organic light-emitting diodes (OLEDs), quantum-dot light-emitting diodes (QLEDs), inorganic micro-light-emitting diodes (e.g., micro-LEDs), and/or inorganic nano-light-emitting diodes (nano-LEDs).

The color conversion substrate 2 may be positioned on and face the display substrate 1. According to some embodiments, the color conversion substrate 2 may include color conversion patterns, which convert the color of incident light. According to some embodiments, the color conversion patterns may include color filters and/or wavelength conversion patterns.

The sealing part 4 may be positioned between the display substrate 1 and the color conversion substrate 2 in the non-display area NDA. The sealing part 4 may be arranged along the edges of the display substrate 1 and the color conversion substrate 2 in the non-display area NDA and may surround the display area DA in a plan view. The display substrate 1 and the color conversion substrate 2 may be coupled to each other via the sealing part 4.

The filler 3 may be positioned in the space surrounded by the sealing part 4 between the display substrate 1 and the color conversion substrate 2. The filler 3 may fill the space between the display substrate 1 and the color conversion substrate 2. The filler 3 may be formed of a light-transmissive material. According to some embodiments, the filler 3 may be omitted.

According to some embodiments, the color conversion substrate 2, the filler 3, and the sealing part 4 may be omitted. For example, in a case where an encapsulation structure, such as a thin-film encapsulation layer TFEL that will be described later, is included in the display device DD, sub-components of the color conversion substrate 2 may be directly located on the thin-film encapsulation layer TFEL, rather than on the color conversion substrate 2, the filler 3, and the sealing part 4.

For convenience, the display device DD will hereinafter be described as including the color conversion substrate 2, the filler 3, and the sealing part 4.

FIG. 12 is an enlarged cross-sectional view of area A of FIG. 11.

Referring to FIG. 12, the display device DD may include the display substrate 1, the color conversion substrate 2, which faces the display substrate 1, and the filler 3, which is filled between the display substrate 1 and the color conversion substrate 2.

The display substrate 1 may include a first base substrate SUB1, a circuit layer CCL, a pixel-defining film PDL, light-emitting elements EMD, and the thin-film encapsulation layer TFEL.

The first base substrate SUB1 may include a transparent material. For example, the first base substrate SUB1 may include a transparent insulating material such as glass or quartz. The first base substrate SUB1 may be a rigid substrate, but the present disclosure is not limited thereto. Alternatively, the first base substrate SUB1 may include plastics such as polyimide, and may have flexible characteristics that allow it to be bent, folded, or rolled.

The circuit layer CCL may be located on the first base substrate SUB1. The circuit layer CCL may include transistors and various circuit wirings that drive the light-emitting elements EMD. The circuit layer CCL may be located between the first base substrate SUB1 and the light-emitting elements EMD.

The pixel-defining film PDL may be located on pixel electrodes PXE along the boundaries of each pixel PX. The pixel-defining film PDL may include openings that expose at least parts of the pixel electrodes PXE. Light-emitting areas and non-light-emitting areas may be distinguished from one another by the pixel-defining film PDL and its openings.

The pixel-defining film PDL may include an organic insulating material such as an acrylic resin, an epoxy resin, a phenolic resin, a polyamide resin, a polyimide resin, an unsaturated polyester resin, a polyphenylene ether resin, a polyphenylene sulfide resin, or benzocyclobutene (BCB). The pixel-defining film PDL may also include an inorganic material.

The light-emitting elements EMD may be located on the circuit layer CCL. FIG. 12 illustrates one pixel PX and one light-emitting element EMD, but the display substrate 1 may include a plurality of light-emitting elements EMD, which are located in each pixel PX.

The light-emitting elements EMD may include the pixel electrodes PXE, light-emitting layers EML, and a common electrode CME.

The pixel electrodes PXE may be located on the circuit layer CCL of the display substrate 1. The pixel electrodes PXE may be the first electrodes (e.g., the anode electrodes) of the light-emitting elements EMD. Each of the pixel electrodes PXE may have a layered film structure comprising a layer of a material with a high work function, such as indium-tin-oxide (ITO), indium-zinc-oxide (IZO), zinc oxide (ZnO), indium oxide (In₂O₃), and a layer of a reflective material, such as silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca), or a mixture thereof. The high work function material layer may be located above the reflective material layer, closer to the light-emitting layer EML. The pixel electrodes PXE may have a multilayer structure such as ITO/Mg, ITO/MgF, ITO/Ag, or ITO/Ag/ITO, but the present disclosure is not limited thereto.

The light-emitting layers EML may be located on the pixel electrodes PXE exposed by the pixel-defining film PDL. In embodiments where the display device DD is an organic light-emitting display device, the light-emitting layers EML may include organic layers containing an organic material. The organic layers may include organic light-emitting layers and may optionally include auxiliary layers such as hole injection layers, hole transport layers, electron transport layers, and electron injection layers. According to some embodiments where the display device DD is a micro- or nano-LED display device, the light-emitting layers EML may include an inorganic material such as an inorganic semiconductor.

According to some embodiments, the light-emitting layers EML of all pixels PX may emit light of the same wavelength. For example, if the light-emitting layer EML of each pixel PX emits blue light or ultraviolet (UV) light, and the color conversion substrate 2 includes wavelength conversion layers WCL, color display can be enabled in each pixel PX. According to some embodiments, the wavelength of each light-emitting layer EML may vary from one pixel PX to another pixel PX.

The common electrode CME may be located on the light-emitting layers EML. The common electrode CME may be connected across all pixels PX. The common electrode CME may be a full electrode extending across all pixels PX without distinction. The common electrode CME may be the second electrode (e.g., the cathode electrode) of the light-emitting elements EMD. The common electrode CME may include a layer of a material with a low work function, such as Li, Ca, LiF/Ca, LiF/Al, Al, Mg, Ag, Pt, Pd, Ni, Au, Nd, Ir, Cr, BaF, Ba, or a compound or mixture thereof (e.g., the mixture of Ag and Mg). The common electrode CME may also include a layer of a transparent metal oxide, which is located on the low work function material layer.

The thin-film encapsulation layer TFEL may be located on the common electrode CME. The thin-film encapsulation layer TFEL may include a first inorganic layer TFE1, an organic layer TFE2, and a second inorganic layer TFE3.

The first inorganic layer TFE1 may be located on the light-emitting elements EMD. The first inorganic layer TFE1 may include silicon nitride (SiNₓ), silicon oxide (SiOₓ), or silicon oxynitride (SiOₓN_{y}).

The organic layer TFE2 may be located on the first inorganic layer TFE1. The organic layer TFE2 may include an organic insulating material such as an acrylic resin, an epoxy resin, a phenolic resin, a polyamide resin, a polyimide resin, an unsaturated polyester resin, a polyphenylene ether resin, a polyphenylene sulfide resin, or BCB.

The second inorganic layer TFE3 may be located on the organic layer TFE2. The second inorganic layer TFE3 may include the same material as the first inorganic layer TFE1. For example, the second inorganic layer TFE3 may include silicon nitride (SiNₓ), silicon oxide (SiOₓ), or silicon oxynitride (SiOₓN_{y}).

The color conversion substrate 2 may be located on the thin-film encapsulation layer TFEL to face the display substrate 1. For example, the color conversion substrate 2 may be arranged to face the display substrate 1 with the filler 3 interposed therebetween.

The color conversion substrate 2 may include a second base substrate SUB2, a black matrix BML, color filter layers CFL, a first capping layer CAP1, a partition layer PTL, wavelength conversion layers WCL, and a second capping layer CAP2.

The second base substrate SUB2 may include a transparent material. For example, the second base substrate SUB2 may include a transparent insulating material such as glass or quartz. The second base substrate SUB2 may be a rigid substrate, but the present disclosure is not limited thereto. Alternatively, the second base substrate SUB2 may include plastics such as polyimide and may have flexible characteristics that allow it to bend, folded, or rolled.

The same substrate as the first base substrate SUB1 may be used as the second base substrate SUB2, but the first and second base substrates SUB1 and SUB2 may differ in material, thickness, and transmittance. For example, the second base substrate SUB2 may have a higher transmittance than the first base substrate SUB1. The second base substrate SUB2 may be thicker or thinner than the first base substrate SUB1.

The black matrix BML may be located on one surface of the second base substrate SUB2 that faces the first base substrate SUB1, along the boundaries of each pixel PX. The black matrix BML may overlap with the pixel-defining layer PDL of the display substrate 1. According to some embodiments, the black matrix BML may include openings that expose the surface of the second base substrate SUB2 and may be formed in a lattice shape in a plan view.

The black matrix BML may be formed of an organic material. The black matrix BM may absorb external light, reducing color distortion caused by reflected external light. The black matrix BML may also prevent or reduce light emitted from the light-emitting layers EML from encroaching into adjacent pixels PX.

The color filter layers CFL may be located on the surface of the second base substrate SUB2 where the black matrix BML is positioned. The color filter layers CFL may be located on the exposed surface of the second base substrate SUB2 through the openings of the black matrix BML.

The color filter layers CFL may include colorants such as dyes or pigments, that absorb wavelengths other than their corresponding color wavelengths. The color filter layers CFL of different pixels PX may include different colorants. For example, the color filter layers CFL may include red, green, and blue colorants.

The first capping layer CAP1 may be located on the color filter layers CFL. The first capping layer CAP1 may prevent or reduce the infiltration of impurities such as moisture or air. Additionally, the first capping layer CAP1 may prevent or reduce the diffusion of the colorants in the color filter layers CFL into other components.

The partition layer PTL may be located on the first capping layer CAP1. The partition layer PTL may be arranged to overlap with the black matrix BML. The partition layer PTL may include openings that expose areas where the color filter layers CFL are located. The partition layer PTL may be formed of a photosensitive organic material, but the present disclosure is not limited thereto. The partition layer PTL may also include a light-blocking material.

The wavelength conversion layers WCL may be located within the spaces exposed by the openings of the partition layer PTL.

The wavelength conversion layers WCL may convert the wavelength of light incident from the light-emitting layers EML. Each of the wavelength conversion layers WCL may include a base resin BRS, a scatterer SCP, which is located within the base resin BRS, and a wavelength conversion material WCP, which is also located within the base resin BRS.

The base resin BRS may include a light-transmitting organic material. For example, the base resin BRS may be formed of an epoxy resin, an acrylic resin, a cardo resin, or an imide resin.

The wavelength conversion material WCP may be a color-changing material. The wavelength conversion material WCP may include quantum dots, quantum rods, or phosphors. The quantum dots may include group IV nano-crystals, group II-VI compound nano-crystals, group Ill-V compound nano-crystals, group IV-VI nano-crystals, or a combination thereof.

According to some embodiments, the wavelength conversion layers WCL may not include the wavelength conversion material WCP. If the wavelength conversion layers WCL do not contain the wavelength conversion material WCP, the wavelength conversion layers WCL may act as light-transmitting layers, allowing light to pass through.

The scatterer SCP may be either particles of a metal oxide or particles of an organic material. The metal oxide may be titanium dioxide (TiO₂), zirconium dioxide (ZrO₂), Al₂O₃, In₂O₃, ZnO, or tin oxide (SnO₂), and the organic material may be an acrylic resin or a urethane resin.

The second capping layer CAP2 may be located on the wavelength conversion layer WCL and the partition layer PTL. The second capping layer CAP2 may also be located on the entire surface of the color conversion substrate 2. The second capping layer CAP2 may prevent or reduce the infiltration of impurities or contaminants such as moisture or air. The second capping layer CAP2 may be formed of an inorganic material. The second capping layer CAP2 may be formed of a material selected from among those listed above for the first capping layer CAP1. The second capping layer CAP2 may be formed of the same material as the first capping layer CAP2, but the present disclosure is not limited thereto.

The filler 3 may be located between the display substrate 1 and the color conversion substrate 2. The filler 3 fills the space between the display substrate 1 and the color conversion substrate 2 and bonds the display substrate 1 and the color conversion substrate 2 together. The filler 3 may be located between the thin-film encapsulation layer TFEL of the display substrate 1 and the second capping layer CAP2 of the color conversion substrate 2. The filler 3 may be formed of a silicon (Si)-based organic material or an epoxy-based organic material, but the present disclosure is not limited thereto.

According to some embodiments, certain organic/inorganic layers included in the circuit layer CCL, certain organic/inorganic layers in the thin-film encapsulation layer TFEL, and certain organic/inorganic layers in the color conversion substrate 2 may be formed by the deposition apparatus 1000 according to any one of the aforementioned embodiments.

In concluding the detailed description, those skilled in the art will appreciate that many variations and modifications can be made to the disclosed embodiments without substantially departing from the principles of the present disclosure. Therefore, the disclosed embodiments of the invention are used in a generic and descriptive sense only and not for purposes of limitation.

What is claimed is:

1. A deposition apparatus comprising:
a reaction chamber;
a radio frequency (RF) power supply device configured to provide RF power to the reaction chamber;
an RF sensing device configured to sense the RF power at each sub-unit time of each of multiple unit times;
a computing device configured to compute an average value of intensities of the RF power measured at each sub-unit time of each of the unit times; and
a fault detection and classification (FDC) device configured to:
determine an occurrence of an arc based on the calculated average value of the intensities of the RF power; and
generate a command signal based on the occurrence of the arc to control a reaction process.

2. The deposition apparatus of claim 1, wherein
the RF power includes forward wave power and reflected wave power, and
an intensity of the RF power is equal to a sum of intensities of the forward wave power and the reflected wave power.

3. The deposition apparatus of claim 2, wherein
the unit times include a first unit time, a second unit time, and a third unit time in chronological order,
an average value of intensities of the forward wave power computed during the first unit time is FPₙ₋₂,
an average value of intensities of the forward wave power computed during the second unit time is FPₙ₋₁,
an average value of intensities of the forward wave power computed during the third unit time is FPₙ,
the FDC device is further configured to generate a “GO” command if Equation (1) is not satisfied, and
Equation (1) is as follows:
$$F {P}_{n} \leq ( F {P}_{n - 2} + F {P}_{n - 1} ) / 2 * {σ}_{1} , 0.7 \leq {σ}_{1} \leq 0.9 . \qquad ( 1 )$$

4. The deposition apparatus of claim 3, wherein
the FDC device is further configured to generate a “WARNING” command based on Equation (1) being satisfied and Equation (2) not being satisfied, and Equation (2) is as follows:
$${FP}_{n} \leq ( {FP}_{n - 2} + {FP}_{n - 1} / 2 * {σ}_{2} , 0.2 \leq {σ}_{2} \leq 0.5 . \qquad ( 2 )$$

5. The deposition apparatus of claim 4, wherein the FDC device is further configured to generate a “STOP” command based on both Equations (1) and (2) being satisfied.

6. The deposition apparatus of claim 2, wherein
the unit times include a first unit time, a second unit time, and a third unit time in chronological order,
an average value of intensities of the reflected wave power computed during the first unit time is RPₙ₋₂,
an average value of intensities of the reflected wave power computed during the second unit time is RPₙ₋₁,
an average value of intensities of the reflected wave power computed during the third unit time is RPₙ,
the FDC device is further configured to generate a “GO” command based on Equation (3) not being satisfied, and
Equation (3) is as follows:
$$R {P}_{n} \geq ( R {P}_{n - 2} + R {P}_{n - 1} ) / 2 * {σ}_{3} , 1.1 \leq {σ}_{3} \leq 1.3 . \qquad ( 3 )$$

7. The deposition apparatus of claim 6, wherein
the FDC device is further configured to generate a “WARNING” command based on Equation (3) being satisfied and Equation (4) not being satisfied, and Equation (4) is as follows:
$$R {P}_{n} \geq ( R {P}_{n - 2} + R {P}_{n - 1} ) / 2 * {σ}_{4} , 1.5 \leq {σ}_{4} \leq 1.8 . \qquad ( 4 )$$

8. The deposition apparatus of claim 7, wherein the FDC device is further configured to generate a “STOP” command based on both Equations (3) and (4) being satisfied.

9. The deposition apparatus of claim 1, wherein 100 or more sub-unit times are included in each of the unit times.

10. The deposition apparatus of claim 9, wherein the sub-unit times are 10 milliseconds (msec) or less.

11. The deposition apparatus of claim 10, wherein the sub-unit times are 1 msec.

12. The deposition apparatus of claim 11, wherein the unit times are 2 second (sec).

13. The deposition apparatus of claim 12, wherein the unit times are 1 sec.

14. The deposition apparatus of claim 1, wherein the RF sensing device includes at least one of a data acquisition (DAQ) system or a programmable logic controller (PLC) system.

15. A deposition apparatus comprising:
a reaction system including a reaction chamber and a radio frequency (RF) power supply device configured to provide RF power to the reaction chamber; and
an inspection system, the inspection system including:
an RF sensing device configured to sense the RF power at each sub-unit time of each of multiple unit times and thereby generate a plurality of RF sensing signals including information on an intensity of the RF power;
a computing device configured to collect the RF sensing signals at each of the unit times and thereby generate a plurality of processed data signals including information on an average value of intensities of the RF power measured at each sub-unit time of each of the unit times; and
a fault detection and classification (FDC) device configured to determine a state of the RF power based on the processed data signals and generate a command signal for the state of the RF power,
wherein the FDC device is further configured to provide the command signal to the reaction system.

16. The deposition apparatus of claim 15, wherein
the RF power includes forward wave power and reflected wave power, and
an intensity of the RF power is equal to a sum of intensities of the forward wave power and the reflected wave power.

17. The deposition apparatus of claim 16, wherein
the unit times include a first unit time, a second unit time, and a third unit time in chronological order,
an average value of intensities of the forward wave power computed during the first unit time is FPₙ₋₂,
an average value of intensities of the forward wave power computed during the second unit time is FPₙ₋₁,
an average value of intensities of the forward wave power computed during the third unit time is FPₙ,
the FDC device is further configured to generate a “GO” command if Equation (1) is not satisfied, and
Equation (1) is as follows:
$$F {P}_{n} \leq ( F {P}_{n - 2} + F {P}_{n - 1} ) / 2 * {σ}_{1} , 0.7 \leq {σ}_{1} \leq 0.9 . \qquad ( 1 )$$

18. The deposition apparatus of claim 17, wherein
the FDC device is further configured to generate a “WARNING” command based on Equation (1) being satisfied and Equation (2) not being satisfied, Equation (2) is as follows:
$${FP}_{n} \leq ( {FP}_{n - 2} + {FP}_{n - 1} ) / 2 * {σ}_{2} , 0.2 \leq {σ}_{2} \leq 0.5 , \qquad ( 2 )$$
the FDC device is further configured to generate a “STOP” command based on both Equations (1) and (2) being satisfied.

19. The deposition apparatus of claim 16, wherein
the unit times include a first unit time, a second unit time, and a third unit time in chronological order,
an average value of intensities of the reflected wave power computed during the first unit time is RPₙ₋₂,
an average value of intensities of the reflected wave power computed during the second unit time is RPₙ₋₁,
an average value of intensities of the reflected wave power computed during the third unit time is RPₙ,
the FDC device is further configured to generate a “GO” command based on Equation (3) not being satisfied, and
Equation (3) is as follows:
$$R {P}_{n} \geq ( R {P}_{n - 2} + R {P}_{n - 1} ) / 2 * {σ}_{3} , 1.1 \leq {σ}_{3} \leq 1.3 . \qquad ( 3 )$$

20. The deposition apparatus of claim 19, wherein
the FDC device is further configured to generate a “WARNING” command based on Equation (3) being satisfied and Equation (4) not being satisfied, Equation (4) is as follows:
$$R {P}_{n} \geq ( R {P}_{n - 2} + R {P}_{n - 1} ) / 2 * {σ}_{4} , 1.5 \leq {σ}_{4} \leq 1.8 , \qquad ( 4 )$$
and
the FDC device is further configured to generate a “STOP” command based on both Equations (3) and (4) being satisfied.
